(19) United States
(12) Patent Application Publication
(10) Pub. No.: US 2024/0112885 A1
(43) Pub. Date: Apr. 4, 2024

(54) WIRELESS DATA COMMUNICATION IN PLASMA PROCESS CHAMBER THROUGH VI SENSOR AND RF GENERATOR

(71) Applicant: Applied Materials, Inc., Santa Clara, CA (US)

(72) Inventor: Chuang-Chia Lin, San Ramon, CA (US)

(21) Appl. No.: 18/220,020

(22) Filed: Jul. 10, 2023

Related U.S. Application Data
(60) Provisional application No. 63/412,278, filed on Sep. 30, 2022.

(51) Int. Cl. H01J 37/32

(52) U.S. Cl. CPC H01J 37/3211; H01J 37/32091; H01J 37/32926

(57) ABSTRACT

Embodiments disclosed herein include a diagnostic substrate. In an embodiment, the diagnostic substrate comprises a substrate and a sensor on the substrate. In an embodiment, the diagnostic substrate further comprises a communication module on the substrate that is communicatively coupled to the sensor. In an embodiment, the communication module comprises an output antenna, a switch coupled to the output antenna, and a signal source coupled to the switch.

### CROSS-REFERENCE TO RELATED APPLICATIONS

This application claims the benefit of U.S. Provisional Application No. 63/412,278, filed on Sep. 30, 2022, the entire contents of which are hereby incorporated by reference herein.

### BACKGROUND

### 1) Field

Embodiments relate to the field of semiconductor manufacturing and, in particular, to wireless communication architectures for uploading and downloading information from a sensor in a semiconductor tool.

### 2) Description of Related Art

Instrumented substrates have been developed in order to monitor processing conditions within a chamber. For example, instrumented substrates may include temperature sensors, pressure sensors, electrical sensors (e.g., plasma condition sensors), and the like. In many instances, the data collected by the instrumented substrate is stored in a memory that is provided on the instrumented substrate. After processing, the instrumented substrate can be removed from the chamber, and the collected data can be downloaded to an external device for data processing, analysis, and the like.

However, real time data communication between the instrumented substrate and the external device is a superior solution. Unfortunately, strong electromagnetic fields present in the chamber often induce radio interference and block wireless communication links.

### SUMMARY

Embodiments disclosed herein include a diagnostic substrate. In an embodiment, the diagnostic substrate comprises a substrate and a sensor on the substrate. In an embodiment, the diagnostic substrate further comprises a communication module on the substrate that is communicatively coupled to the sensor. In an embodiment, the communication module comprises an output antenna, a switch coupled to the output antenna, and a signal source coupled to the switch.

Embodiments disclosed herein may also include a diagnostic substrate that comprises a substrate, and a sensor on the substrate. In an embodiment, the diagnostic substrate further comprises a communication module on the substrate that is communicatively coupled to the sensor. In an embodiment, the communication module comprises an input antenna, where the input antenna is configured to collect modulated data, a demodulator coupled to the input antenna, and a controller, where the controller is configured to control the sensor.

Embodiments disclosed herein may also include a plasma processing tool. In an embodiment, the plasma processing tool comprises a chamber configured to contain a plasma, and an RF generator coupled to the chamber, where power from the RF generator is configured to be coupled into one or more gasses in the chamber to form the plasma. The plasma processing tool further comprises a voltage-current (VI) sensor between the RF generator and the chamber, and a diagnostic substrate within the chamber. In an embodiment, the diagnostic substrate comprises a substrate, a sensor on the substrate, and a communication module coupled to the sensor, where the communication module is configured to wirelessly communicate with a device outside of the chamber using carrier signals at a carrier frequency that is an integer multiple of a frequency of the plasma.

### BRIEF DESCRIPTION OF THE DRAWINGS

FIG. 1 is a cross-sectional illustration of a plasma chamber with an RF generator and a VI sensor, in accordance with an embodiment.

FIG. 2A is a schematic illustration of an instrumented substrate with a communication module that is configured to download data from the instrumented substrate to an external device, in accordance with an embodiment.

FIG. 2B is a schematic illustration of an instrumented substrate with a communication module that comprises only an output antenna, in accordance with an embodiment.

FIG. 3 is a cross-sectional illustration of a plasma chamber with a first RF generator coupled to a chuck, and a second RF generator coupled to a showerhead, in accordance with an embodiment.

FIG. 4 is a schematic illustration of an instrumented substrate with a communication module that is configured to upload data from an external device, in accordance with an embodiment.

FIG. 5A is a schematic illustration of an instrumented substrate with a communication module configured to transmit data between the instrumented substrate and an external device, in accordance with an embodiment.

FIG. 5B is a schematic illustration of an instrumented substrate with a communication module configured to transmit data between the instrumented substrate and an external device, in accordance with an additional embodiment.

FIG. 6 illustrates a block diagram of an exemplary computer system that may be used in conjunction with a processing tool, in accordance with an embodiment.

### DETAILED DESCRIPTION

Systems described herein include wireless communication architectures for uploading and downloading information from a sensor in a semiconductor tool. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, instrumented substrates are currently limited in their ability to wirelessly communicate with external devices. As such, it is common for instrumented substrates to store data on an onboard memory, and the data is extracted from the memory after the processing is completed and the instrumented substrate is removed from the plasma chamber. However, wireless communication is a superior data transfer mechanism and allows for real time data analysis and processing. Unfortunately, the strong electromagnetic field within the plasma chamber induces interference and may make traditional wireless communication protocols (e.g., WiFi, Bluetooth, etc.) unsuitable or inaccurate.

Accordingly, embodiments disclosed herein include wireless communication solutions that use the RF signal used to induce the plasma, or (minute modulated variation of) the plasma itself, as a carrier for the data signal to/from the instrumented substrate. In a first embodiment, data is wirelessly downloaded from the instrumented substrate. In such embodiments, a signal source (e.g., a clock or a signal multiplier) provides a signal with a frequency that is significantly different than the RF signal. For example, the signal may be an order of magnitude higher than the RF signal. The high frequency signal is then modulated with a modulator and/or switch that is coupled to an output antenna. As the output antenna is switched on/off the impedance varies. This variation in impedance can be detected by a capacitive or inductive RF pick up sensor that is connected to the RF feedline. Demodulation of the signal can then be implemented in order to extract the data transmitted by the instrumented substrate.

Embodiments may also allow for data uploading to the instrumented substrate. The data upload is implemented by mixing a high-frequency modulation to the RF generator. The high-frequency modulation may be at least an order of magnitude higher than the frequency of the RF signal. An input antenna on the instrumented substrate may be configured to receive the high frequency modulation. A demodulator on the instrumented substrate can then be used to extract the data for use by a controller on the instrumented substrate.

As used herein, an instrumented substrate may refer to a substrate that includes one or more sensors. The substrate may have a form factor of a typical substrate that is processed in a plasma chamber. For example, the substrate may have a wafer form factor (e.g., 150 mm, 200 mm, 300 mm 450 mm, etc.). Though, it is to be appreciated that other form factors, including non-circular form factors, may also be used for the instrumented substrate. The one or more sensor may be distributed across a surface of the substrate in order to provide spatial data collection. In an embodiment, the sensors may include any type of sensor. For example, the sensors may include pressure sensors, temperature sensors, electrical sensors (e.g., to detect one or more plasma processing conditions), optical sensors, and the like.

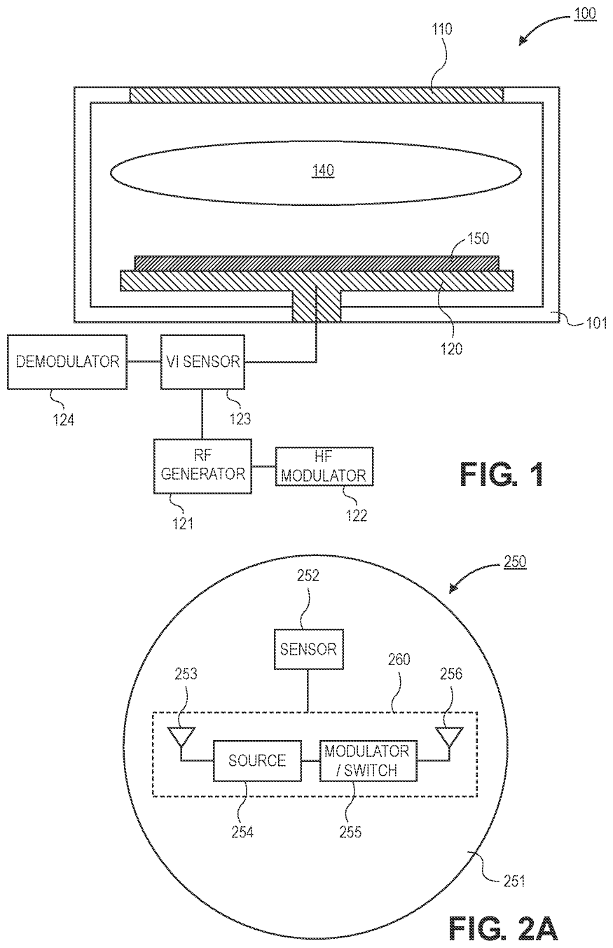

Referring now to FIG. 1, a cross-sectional illustration of a plasma processing tool 100 is shown, in accordance with an embodiment. In an embodiment, the plasma processing tool 100 may comprise a chamber 101. The chamber 101 may be suitable for containing a plasma 140. For example, the chamber 101 may be a vacuum chamber. Exhausts, pumps, etc. that enable low pressure operation are omitted in order to more clearly illustrate certain portions of the embodiment.

In an embodiment, the chamber 101 may comprise a pedestal or chuck 120. The chuck 120 may include a mechanism for securing a substrate, such as an instrumented substrate 150. For example, the chuck 120 may be an electrostatic chuck (ESC). The chuck 120 may also include gas lines to provide backside gas flow and/or heating and cooling solutions in order to control a temperature of the instrumented substrate 150. A showerhead 110 or the like may be provided opposite from the chuck 120. The showerhead 110 may be configured to flow one or more processing gasses, inert gasses, or the like into the chamber.

In an embodiment, the chuck 120 may be coupled to an RF generator 121. The RF generator 121 provides power that is coupled into the chamber 101 in order to strike and maintain the plasma 140. Typically, the RF generator 121 operates at a frequency of approximately 13 MHz (e.g., 13.56 MHz). In an embodiment, a match (not shown) may be provided between the RF generator 121 and the chuck 120. Additionally, a VI sensor 123 may be provided between the chuck 120 and the RF generator 121. The VI sensor 123 may be configured to detect a modulated signal generated by the instrumented substrate 150. The process for generating the modulated signal is described in greater detail below. A demodulator 124 may be coupled to the VI sensor in order to extract the data from the modulated signal from the instrumented substrate 150. In an embodiment, a high-frequency (HF) modulator 122 may also be coupled to the RF generator 121. The HF modulator 122 may be used to upload data to the instrumented substrate 150, as will be described in greater detail below.

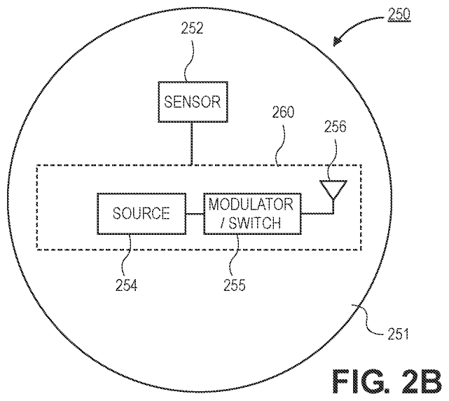

Referring now to FIGS. 2A and 2B, a pair of schematic illustrations of instrumented substrates 250 configured to download data from the instrumented substrate 250 to an external source is shown, in accordance with an embodiment.

Referring now to FIG. 2A, a schematic illustration of an instrumented substrate 250 with a communication module 260 is shown, in accordance with an embodiment. In an embodiment, the communication module 260 may be communicatively coupled to a sensor 252. While a single sensor 252 is shown, it is to be appreciated that any number of sensors 252 may be provided on the instrumented substrate 250 and communicatively coupled to the communication module 260. The sensor 252 may be a temperature sensor, a pressure sensor, a plasma property sensor, an optical sensor, or the like. In an embodiment, data from the sensor 252 is wirelessly communicated to an external device through the use of the communication module 260.

In an embodiment, the communication module 260 may comprise an input antenna 253. The input antenna 253 may be configured to detect the RF frequency and phase used to generate the plasma 140. For example, the input antenna 253 may be configured to detect frequencies around 13 MHz. The input antenna 253 may be any antenna configuration. For example, the input antenna 253 may be coil antenna or the like.

The input antenna 253 may be coupled to a frequency generator 254. In the case of a multiplier, the frequency generator 254 multiplies the frequency of the signal detected by the input antenna 253. For example, the multiplier may multiply the frequency by an integer multiple. In some embodiments, the multiplier may increase the frequency by an order of magnitude or more. The multiplier may be implemented by any suitable circuitry and components, such as diodes, varactors, micro-electromechanical systems (MEMS), phase locked loops (PLLs), and the like.

In an embodiment, the frequency generator 254 may be coupled to a modulator/switch 255. That is, the signal from the frequency generator 254 is provided to the modulator/switch 255. The signal from the frequency generator 254 is used as a carrier signal, and the modulator/switch 255 modulates the carrier signal in order to mix data from the sensor 252 onto the carrier signal. The modulator/switch 255 may use any suitable modulation protocol. For example, modulation may include an ASK modulation, a PSK modulation, a BPSK modulation, or an FSK modulation. In some embodiments, a single modulation channel is used. In other embodiments, two or more modulation channels can be used to increase the bandwidth of the data transfer.

In an embodiment, the modulator/switch 255 is coupled to an output antenna 256. The output antenna 256 is switched on/off by the modulator/switch 255. When the output antenna 256 is on there is a first impedance, and when the output antenna 256 is off, there is a second impedance which is different than the first impedance. The switching of the impedance can then be detected by the VI sensor 123 of the plasma processing tool 100. The demodulator 124 can then demodulate the signal in order to extract the data. The output antenna 256 may be any antenna topology. For example, the antenna may be a coil antenna.

Referring now to FIG. 2B, a schematic illustration of an instrumented substrate 250 is shown, in accordance with an additional embodiment. In an embodiment, the instrumented substrate 250 in FIG. 2B may be substantially similar to the instrumented substrate 250 in FIG. 2A, with the exception of the communication module 260. Instead of having both an input antenna 253 and an output antenna 256, the communication module 260 in FIG. 2B only includes an output antenna 256. The input antenna 253 may be omitted when the RF frequency is a known quantity. For example, RF plasmas typically operate at 13.56 MHz. In such an embodiment, the source 254 may be set to a frequency that is substantially higher than the known frequency. For example, the source 254 may be a clock that has a frequency set to over 100 MHz. The signal from the source 254 can then be used as a carrier signal that is modulated by the modulator/switch 255. The output antenna 256 switches on/off and induces an impedance change that can be detected by the VI sensor 123 of the plasma processing tool.

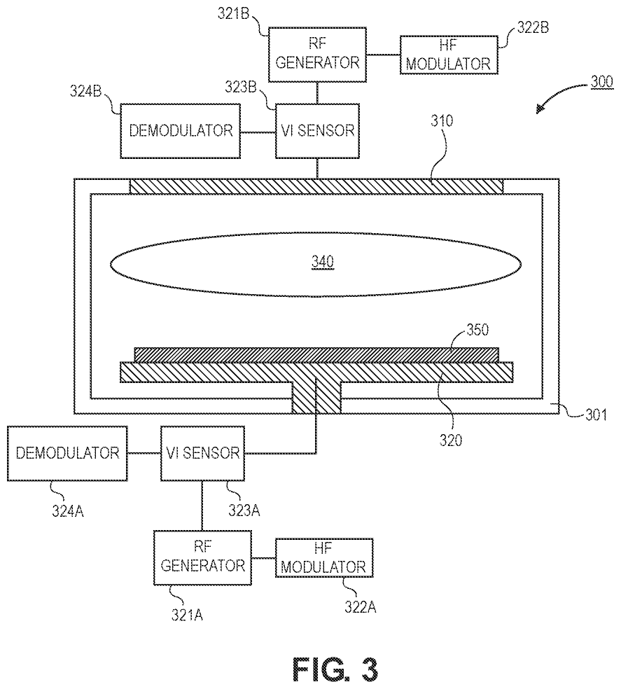

Referring now to FIG. 3, a cross-sectional illustration of a plasma processing tool 300 is shown, in accordance with an embodiment. In an embodiment, the plasma processing tool 300 may be substantially similar to the plasma processing tool 100 described above, with the exception of another RF generator 321B being coupled to the showerhead 310. That is, the plasma processing tool 300 may comprise a chamber 301, a chuck 320, a plasma 340, and the showerhead 310. A first RF generator 321A, a first VI sensor and chamber match 323A, a first demodulator 324A, and a first HF modulator 322A may be coupled to the chuck 320. Similarly, a second RF generator 321B, a second VI sensor 323B, a second demodulator 324B, and a second HF modulator 322B may be coupled to the showerhead.

That is, embodiments are not limited to a single RF frequency. In some embodiments, different RF frequencies may be used for the first RF generator 321A and the second RF generator 321B. The different frequencies can both be used as communication paths in order to download (or upload) data from (or to) the instrumented substrate 350.

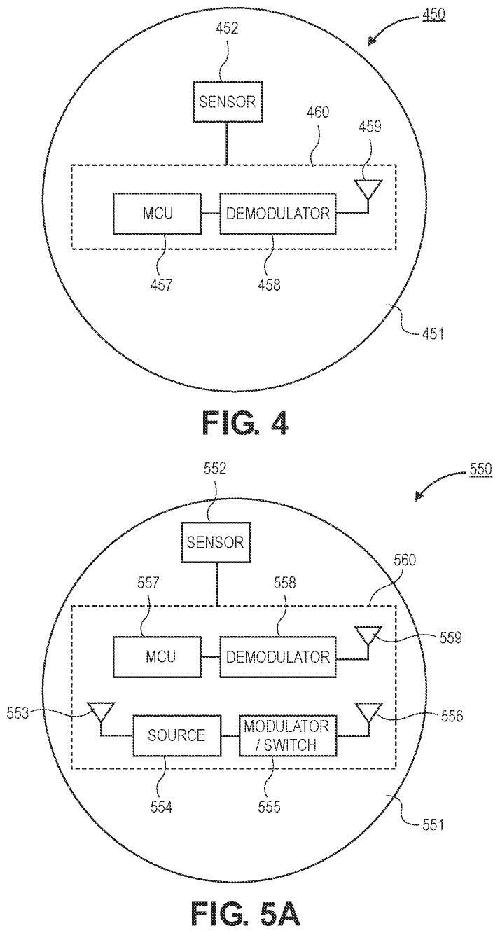

Referring now to FIG. 4, a schematic view illustration of an instrumented substrate 450 is shown, in accordance with an embodiment. In an embodiment, the instrumented substrate 450 includes a sensor 452 that is coupled to a communication module 460. While a single sensor 452 is shown, it is to be appreciated that any number of sensors 452 may be coupled to the communication module 460. The sensor 452 may comprise a temperature sensor, a pressure sensor, a plasma property sensor, an optical sensor, or any other sensor type.

In an embodiment, the communication module 460 may be configured to upload data to the instrumented substrate 450. For example, an external device may provide instructions to the instrumented substrate 450 in order to control the one or more sensors 452. In a particular embodiment, the communication module 460 comprises an input antenna 459, a demodulator 458, and a controller 457 (e.g., a microcontroller unit (MCU)).

In an embodiment, the input antenna 459 is configured to pick up a modulated EM field that is generated by the RF generator through the chuck. The carrier signal may be the RF frequency (or multiple of RF frequency) of the plasma, and the modulated signal may be at a higher or lower frequency. For example, the carrier signal may be an order of magnitude higher or lower than the RF frequency. Providing the modulated signal at frequencies far from the RF frequency allows for the signal to be propagated into the chamber without negatively affecting the plasma performance. In an embodiment, the modulated signal may be added to the RF frequency by an HF modulator similar to the HF modulators 122 and 322 described in greater detail above. The modulated signal may be provided into the chamber at a power less than a power of the RF frequency for the plasma. The input antenna 459 may be any antenna architecture, such as a coil or the like.

After the input antenna 459 receives the modulated signal, the modulated signal is sent to the demodulator 458. The demodulator 458 is configured to extract the data from the modulated signal. In an embodiment, the data can then be provided to the controller 457. The controller 457 can store the data in a memory (not shown) or use the data as instructions for controlling one or more of the sensors 452 on the instrumented substrate 450.

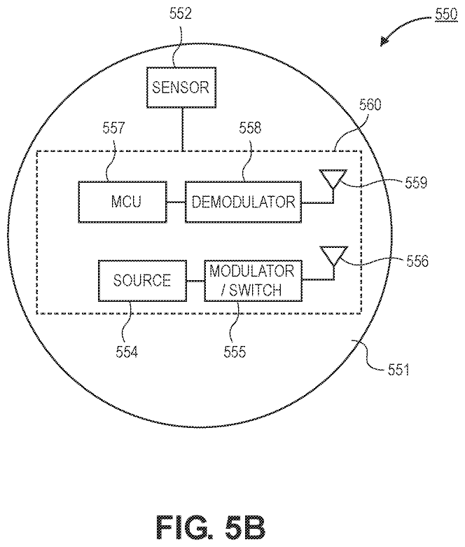

Referring now to FIGS. 5A and 5B, schematic illustrations of instrumented substrates 550 with communication modules 560 are shown, in accordance with an embodiment. As will be appreciated by those skilled in the art, the instrumented substrates 550 may include communication modules 560 that allow for two way communication between the instrumented substrates 550 and an external device.

Referring now to FIG. 5A, a schematic illustration of an instrumented substrate 550 is shown, in accordance with an embodiment. In an embodiment, the instrumented substrate 550 may comprise a sensor 552 that is coupled to a communication module 560. In an embodiment, the sensor 552 may be a single sensor 552, or there may be a plurality of sensors 552 that are coupled to the communication module 560. The sensors 552 may comprise temperature sensors, pressure sensors, plasma property sensors, optical sensors, or the like.

In an embodiment, the communication module 560 may comprise a transmit line and a receive line. In an embodiment, the receive line comprises an input antenna 559, a demodulator 558, and a controller 557. The input antenna 559 is configured to receive a modulated signal that is mixed with the RF frequency. The modulated signal may be at a frequency that is at least an order of magnitude higher or lower than the RF frequency. The modulated signal may contain data that is to be used by the controller 557 to control one or more sensors 552 on the instrumented substrate 550. After the modulated signal is received by the input antenna 559, the demodulator 558 demodulates the signal and provides the extracted data to the controller 557.

In an embodiment, the transmit line may include an input antenna 553, a signal source 554, a modulator/switch 555, and an output antenna 556. In some embodiments, the input antenna 552 picks up the RF frequency of the plasma. The RF frequency is then used by the signal source 554 to produce a carrier frequency. For example, the signal source 554 may be a multiplier that multiplies the RF frequency by an integer multiple. In some embodiments, the signal source 554 may multiply the RF frequency so that it is at least an order of magnitude higher than the RF frequency.

The carrier signal is then transmitted to the modulator/switch 555 which adds a data stream (e.g., data from one or more sensors 552) to the carrier signal using one or more modulation schemes/channels. The modulator/switch 555 may result in the output antenna 556 being switched on/off, or directly switch on/off the input antenna 553, turning 553 to an output antenna. The output antenna 556 (or 553) imparts a first impedance when on and a second (different) impedance when off. The change in the impedance can be detected by the VI sensor (e.g., VI sensor 123 or 323) of the plasma processing tool, and the signal can be demodulated by a demodulator (e.g., demodulator 124 or 324) in order to extract the data for use by an external source.

Referring now to FIG. 5B, a schematic illustration of an instrumented substrate 550 is shown, in accordance with an additional embodiment. As shown, the instrumented substrate 550 is substantially similar to the instrumented substrate 550 in FIG. 5A, with the exception of the transmit line. Instead of having an input antenna 553, the transmit line starts with the signal source 554. For example, the signal source 554 may be a clock. The signal source 554 may be set to a frequency that is known to be different than the RF frequency. For example, RF plasmas typically operate at 13.56 MHz, so the clock of the signal source 554 may be set to generate a carrier signal of 100 MHz or higher.

The carrier signal is then transmitted to the modulator/switch 555 which adds a data stream (e.g., data from one or more sensors 552) to the carrier signal using one or more modulation schemes/channels. The modulator/switch 555 may result in the output antenna 556 being switched on/off. The output antenna 556 imparts a first impedance when on and a second (different) impedance when off. The change in the impedance can be detected by the VI sensor (e.g., VI sensor 123 or 323) of the plasma processing tool, and the signal can be demodulated by a demodulator (e.g., demodulator 124 or 324) in order to extract the data for use by an external source.

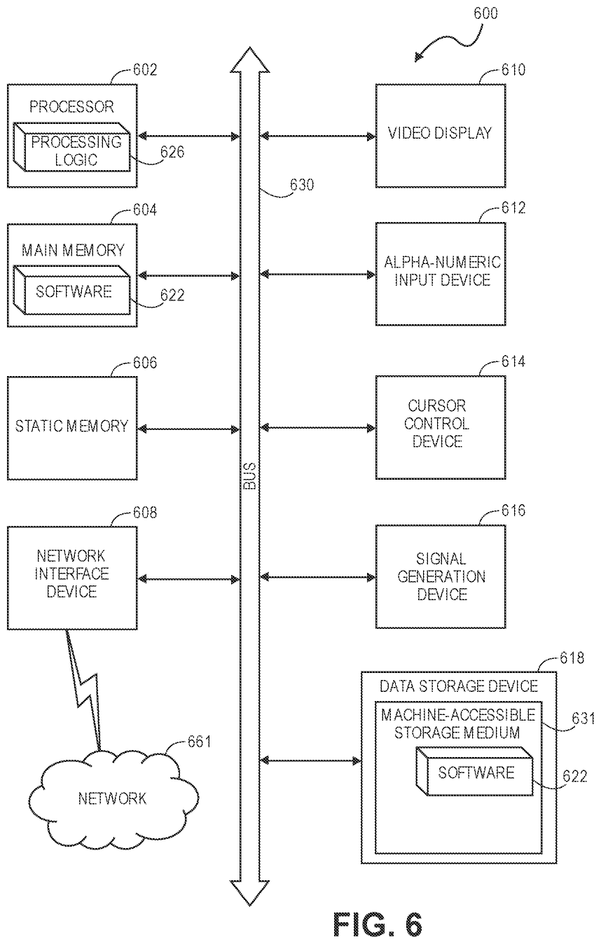

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 632 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 620 via the system network interface device 608. In an embodiment, the network interface device 608 may operate using RF coupling, optical coupling, acoustic coupling, or inductive coupling.

While the machine-accessible storage medium 632 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A diagnostic substrate, comprising:
a substrate;
a sensor on the substrate; and
a communication module on the substrate that is communicatively coupled to the sensor, wherein the communication module comprises:
an output antenna;
a switch coupled to the output antenna; and
a signal source coupled to the switch.

2. The diagnostic substrate of claim 1, wherein the communication module further comprises:
an input antenna coupled to the signal source, wherein the input antenna is configured to obtain a frequency of a plasma by detecting an electromagnetic field change around the substrate, and wherein the signal source is a signal multiplier that multiplies the frequency of the plasma by an integer multiple.

3. The diagnostic substrate of claim 2, wherein the signal multiplier comprises one or more of a diode, a varactor, a micro-electromechanical system (MEMS) device, and a phase locked loop (PLL).

4. The diagnostic substrate of claim 1, wherein the signal source is a clock that generates a frequency that is different from a plasma frequency.

5. The diagnostic substrate of claim 1, wherein the sensor is a temperature sensor, a pressure sensor, an voltage/bias sensor, an optical sensor, or a plasma sensor for detecting one or more of electrons, ions, radicals.

6. The diagnostic substrate of claim 5, wherein the sensor is one sensor of a plurality of sensors.

7. The diagnostic substrate of claim 1, wherein the communication module has a first impedance when the switch is open and a second impedance when the switch is closed.

8. The diagnostic substrate of claim 7, wherein the switch is operated at a frequency correlated to the signal source.

9. The diagnostic substrate of claim 8, wherein the switching frequency is modulated with a ASK modulation, a PSK modulation, a BPSK modulation, or an FSK modulation.

10. The diagnostic substrate of claim 1, wherein the communication module is configured to download information from the diagnostic substrate to an external device through modulation of the impedance through switching of the switch.

11. A diagnostic substrate, comprising:
a substrate;
a sensor on the substrate; and
a communication module on the substrate that is communicatively coupled to the sensor, wherein the communication module comprises:
an input antenna, wherein the input antenna is configured to collect modulated data;
a demodulator coupled to the input antenna; and
a controller, wherein the controller is configured to control the sensor.

12. The diagnostic substrate of claim 11, wherein the input antenna is a high frequency antenna that is configured to pick up frequencies different from plasma frequency.

13. The diagnostic substrate of claim 11, wherein the modulated data transmission is at a lower power level than a plasma power.

14. The diagnostic substrate of claim 11, wherein the modulated data is provided on a carrier frequency delivered from the chamber RF generator, wherein the carrier frequency is at least an order of magnitude higher or lower than a plasma frequency.

15. The diagnostic substrate of claim 11, wherein the carrier frequency is a frequency of a plasma used to process the diagnostic substrate.

16. The diagnostic substrate of claim 11, wherein the communication module is configured to read data from an external RF generator by demodulating a signal from the input antenna.

17. A plasma processing tool, comprising:
a chamber configured to contain a plasma;
an RF generator coupled to the chamber, wherein power from the RF generator is configured to be coupled into one or more gasses in the chamber to form the plasma;
a voltage-current (VI) sensor between the RF generator and the chamber; and
a diagnostic substrate within the chamber, wherein the diagnostic substrate comprises:
a substrate;
a sensor on the substrate; and
a communication module coupled to the sensor, wherein the communication module is configured to wirelessly communicate with a device outside of the chamber using carrier signals at a carrier frequency that is an integer multiple of a frequency of the plasma.

18. The plasma processing tool of claim 17, wherein the communication module comprises:
an input antenna, wherein the input antenna is configured to detect the frequency of the plasma;
a signal multiplier coupled to the input antenna;
a switch coupled to the signal multiplier; and
an output antenna coupled to the switch, and wherein switching the switch on and off results in an impedance change that can be detected by the VI sensor.

19. The plasma processing tool of claim 17, wherein the communication module comprises:
an input antenna, wherein the input antenna is configured to collect modulated data from an RF signal used to form the plasma;
a demodulator coupled to the input antenna; and
a controller, wherein the controller is configured to control the sensor.

20. The plasma processing tool of claim 17, wherein the communication module is configured to upload data from an external device to the substrate and/or download data from the substrate to the external device.
